(19) United States
(12) Patent Application Publication
(10) Pub. No.: US 2014/0272197 A1
(43) Pub. Date: Sep. 18, 2014

(54) DIRECTED VAPOR DEPOSITION OF ENVIRONMENTAL BARRIER COATINGS

(71) Applicant: Rolls-Royce Corporation, Indianapolis, IN (US)

(72) Inventor: Kang N. Lee, Zionsville, IN (US)

(73) Assignee: Rolls-Royce Corporation, Indianapolis, IN (US)

(21) Appl. No.: 14/208,205

(22) Filed: Mar. 13, 2014

Related U.S. Application Data
(60) Provisional application No. 61/780,580, filed on Mar. 13, 2013.

(51) Int. Cl. C23C 16/448

(52) U.S. Cl. CPC C23C 16/448
USPC 427/596

(57) ABSTRACT

In some examples, a method may include directing an electron beam at a coating source to create a vapor plume, wherein the coating source comprises alumina and at least one rare earth oxide. The method also may include transporting the vapor plume using a gas stream provided adjacent to the coating source to within an internal cavity defined by a surface of a substrate of a gas turbine engine blade, vane, blade track, or combustor liner, and wherein the substrate comprises at least one of a silicon-containing ceramic or a ceramic matrix composite. Additionally, the method may include depositing the alumina and the at least one rare earth oxide from the vapor plume over the surface of the internal cavity to form a calcia-magnesia-alumina-silicate (CMAS)-resistant environmental barrier coating (EBC) comprising the alumina and the at least one rare earth oxide.

This application claims the benefit of U.S. Provisional Application No. 61/780,580, filed Mar. 13, 2013, which is incorporated herein by reference in its entirety.

### TECHNICAL FIELD

The present disclosure generally relates to techniques for vapor deposition of environmental barrier coatings.

### BACKGROUND

Components of high-temperature mechanical systems, such as, for example, gas-turbine engines, must operate in severe environments. For example, the high-pressure turbine blades and vanes exposed to hot gases in commercial aeronautical engines typically experience metal surface temperatures of about 1000° C., with short-term peaks as high as 1100° C.

Some components of high-temperature mechanical systems include a Ni or Co-based superalloy substrate. In an attempt to reduce the temperatures experienced by the substrate, the substrate can be coated with a thermal barrier coating (TBC). The TBC may include a thermally insulative ceramic topcoat and is bonded to the substrate by an underlying metallic bond coat.

Economic and environmental concerns, i.e., the desire for improved efficiency and reduced emissions, continue to drive the development of advanced gas turbine engines with higher inlet temperatures. Some components of high-temperature mechanical systems include a ceramic or ceramic matrix composite (CMC) substrate, which may allow an increased operating temperature compared to a component with a superalloy substrate.

### SUMMARY

The disclosure describes techniques for depositing environmental barrier coatings (EBCs) on internal surfaces and non-line-of-sight surfaces of gas turbine engine components. For example, the gas turbine engine components may include gas turbine engine blades, vanes, blade tracks, or combustor liners, and may define internal cavities and surfaces that cannot be coated with line-of-sight processes such as plasma spraying. The gas turbine engine components may include ceramic or CMC substrates. These substrates may be vulnerable to chemical attack by species present in the hot gas or the cooling fluid, including impurities. For example, water vapor may chemically attack the ceramic or CMC substrate at the temperatures experienced by the ceramic or CMC substrate and damage the ceramic or CMC substrate.

In accordance with some examples of this disclosure, a technique includes depositing calcia-magnesia-alumina-silicate (CMAS)-resistant EBCs on internal surfaces and non-line-of-sight surfaces of gas turbine engine components, such as gas turbine blades, vanes, blade tracks or combustor liners. The technique may utilize directed vapor deposition (DVD), which is a novel type of electron beam-physical vapor deposition. In DVD, an electron beam is used to form a vapor plume including the coating components, and a stream of gas is used to direct the vapor plume. Due to the gas stream, the vapor plume may be directed to internal cavities and non-line-of-sight surfaces of components and DVD may be used to deposit coatings on internal surfaces of the components, such as surfaces of cooling channels in a blade or vane.

In some examples, the disclosure describes a method including directing an electron beam at a coating source to create a vapor plume, wherein the coating source comprises alumina and at least one rare earth oxide. The method also may include transporting the vapor plume using a gas stream provided adjacent to the coating source to within an internal cavity defined by a surface of a substrate of a gas turbine engine blade or vane, and wherein the substrate comprises at least one of a silicon-containing ceramic or a ceramic matrix composite. Additionally, the method may include depositing the alumina and the at least one rare earth oxide from the vapor plume over the surface of the internal cavity to form a CMAS-resistant EBC comprising the alumina and the at least one rare earth oxide.

In some examples, the disclosure discloses a method including directing an electron beam at a first coating source to create a first vapor plume, wherein the first coating source comprises alumina and at least one rare earth oxide and directing the electron beam at a second coating source to create a second vapor plume, wherein the second coating source comprises silica. The method also may include transporting the first vapor plume using a first gas stream provided adjacent to the first coating source to within an internal cavity defined by a surface of a substrate of a gas turbine engine blade, vane, blade track, combustor liner, and wherein the substrate comprises at least one of a silicon-containing ceramic or a ceramic matrix composite. Further, the method may include transporting the second vapor plume using a second gas stream provided adjacent to the second coating source to within the internal cavity defined by the surface of the substrate of the gas turbine engine blade, vane, blade track, or combustor liner. The method additionally includes depositing the alumina and the at least one rare earth oxide from the first vapor plume and the silica from the second vapor plume over the surface of the internal cavity or non-line-of-sight surfaces to form a CMAS-resistant EBC comprising the alumina, the silica, and the at least one rare earth oxide.

The details of one or more examples are set forth in the accompanying drawings and the description below. Other features, objects, and advantages will be apparent from the description and drawings, and from the claims.

### BRIEF DESCRIPTION OF THE DRAWINGS

FIG. 1 is a conceptual diagram illustrating an example coating system including a CMAS-resistant EBC.

FIG. 2 is a conceptual, cross-sectional diagram illustrating an example gas turbine engine blade.

FIG. 3 is a flow diagram illustrating an example technique for depositing a CMAS-resistant EBC layer on an internal surface of an article using DVD.

FIG. 4 is a schematic diagram of a system including a vapor deposition chamber that may be used to deposit a CMAS-resistant EBC layer on an internal surface of an article using DVD.

FIGS. 5A-5D are micrographs of example components including EBCs.

FIGS. 6A and 6B are micrographs illustrating a cross-section of an example CMC gas turbine vane inner trailing edge coating with an EBC.

FIG. 7 is micrographs illustrating a cross-section of an example CMC substrate coated with a multilayer EBC.

FIGS. 8A and 8B are micrographs illustrating a superalloy substrate coated with a low thermal conductivity TBC having a tetragonal prime phase constitution.

### DETAILED DESCRIPTION

The disclosure describes techniques for depositing environmental barrier coatings on internal surfaces and non-line-of-sight surfaces of gas turbine engine components. For example, the gas turbine engine components may include gas turbine engine blades, vanes, blade tracks, or combustors liners, and may define internal cavities. In some example, the internal cavities may be fluid channels through which a cooling fluid flows during operation of the gas turbine engine, which cools the interior of the gas turbine engine or blade. Cooling the interior of the gas turbine engine may allow use of higher operating temperatures for the gas turbine engine by maintaining a temperature of the gas turbine engine or blade below the ambient temperature within the gas turbine engine at the location at which the gas turbine engine or blade is used.

Although the cooling channels and cooling fluid may facilitate more efficient operation of the gas turbine engines, ceramic or CMC substrates from which the blades or vanes are formed may be vulnerable to chemical attack by species present in the cooling fluid, including impurities. For example, water vapor may chemically attack the ceramic or CMC substrate at the temperatures experienced by the ceramic or CMC substrate and damage the ceramic or CMC substrate.

In accordance with aspects of this disclosure, a technique includes depositing an environmental barrier coating (EBC) on internal surfaces of gas turbine engine components, such as gas turbine blades or vanes. An EBC can also function as a thermal barrier coating (TBC), or a coating may include a TBC overlay on top of an EBC to further increase the thermal insulation capability. The techniques described herein may utilize directed vapor deposition (DVD), which is a novel type of electron beam-physical vapor deposition (EB-PVD). In DVD, an electron beam is used to form a vapor plume including the coating components, and a stream of gas is used to direct the vapor plume. Due to the gas stream, the vapor plume may be directed to internal cavities of components and DVD may be used to deposit the EBC on internal surfaces of the components, such as surfaces of cooling channels in a blade or vane.

In some examples, the EBC may include a CMAS-resistant composition. As the turbine inlet temperature continues to increase in advanced gas turbine engines, new degradation and failure mechanisms have emerged. One notable degradation is the attack by calcium-magnesium alumino silicate (CMAS) deposits resulting from the ingestion of siliceous minerals (dust, sand, volcanic ash, runway debris) with the intake air, especially in aircraft engines. Typical CMAS deposits have the melting point between about 1200° C. and about 1250° C. (between about 2200° F. and about 2300° F.). At low temperatures, these contaminants can cause erosive wear or local spallation of an EBC when impacting as solid particles.

As engine temperatures increase, the siliceous debris may adhere to the EBC surfaces and yield glassy melts. The glassy melt can penetrate the microstructural features that induce compliance in the coating, such as micro-cracks in EBCs deposited by atmospheric plasma spray (APS) and columnar segmentation in EBCs deposited by electron beam-physical vapor deposition (EB-PVD), leading to a loss of strain tolerance. Another mode of degradation of a coating by CMAS is chemical: yttria-stabilized zirconia (YSZ) and yttria-stabilized hafnia (YSH) may dissolve in molten CMAS, including along grain boundaries of the YSZ and YSH, and monoclinic ZrO₂ or HfO₂ may precipitate with a lower Y content. Similar chemical modes of CMAS attack may occur on an EBC including zirconia or hafnia.

FIG. 1 is a conceptual diagram illustrating an example coating system including a CMAS-resistant EBC. As shown in FIG. 1, an article 10 includes a substrate 12 and a coating system 14. In the example illustrated in FIG. 1, the coating system 14 includes a bond layer 16, a CMAS-resistant EBC 18, and a TBC overlay 20. Although illustrated in FIG. 1, both bond layer 16 and TBC overlay 20 are optional. Other examples of coating system 14 may include only CMAS-resistant EBC 18, bond layer 16 and CMAS-resistant EBC 18, or CMAS-resistant EBC 18 and TBC overlay 20.

Substrate 12 includes a ceramic or ceramic matrix composite. In some examples in which substrate 12 includes a ceramic, the ceramic may be substantially homogeneous. In some examples, a substrate 12 that includes a ceramic includes, for example, a Si-containing ceramic, such SiO₂, silicon carbide (SiC) or silicon nitride (Si₃N₄); Al₂O₃; aluminosilicate (e.g., Al₂SiO₅); or the like. In other examples, substrate 10 includes a metal alloy that includes Si, such as a molybdenum-silicon alloy (e.g., MoSi₂) or a niobium-silicon alloy (e.g., NbSi₂).

In examples in which substrate 12 includes a CMC, substrate 12 includes a matrix material and a reinforcement material. The matrix material includes a ceramic material, such as, for example, SiC, Si₃N₄, Al₂O₃, aluminosilicate, SiO₂, or the like. The CMC further includes a continuous or discontinuous reinforcement material. For example, the reinforcement material may include discontinuous whiskers, platelets, or particulates. As other examples, the reinforcement material may include a continuous monofilament or multifilament weave.

Bond layer 16 is optional and, when present in coating system 14, may include a composition that enhances adhesion of the CMAS-resistant EBC 18 to a substrate. In some examples, a CMAS-resistant EBC 18 can be applied using DVD above a bond layer 16 including doped RE₂Si₂O₇. In other examples, bond layer 16 may include silicon.

CMAS-resistant EBC 18 may be deposited on bond layer 16 or may be deposited directly on substrate 12. In some examples, CMAS-resistant EBC 18 may include at least one rare earth oxide and alumina. The at least one rare earth oxide may include an oxide of at least one of Lu (lutetium), Yb (ytterbium), Tm (thulium), Er (erbium), Ho (holmium), Dy (dysprosium), Tb (terbium), Gd (gadolinium), Eu (europium), Sm (samarium), Pm (promethium), Nd (neodymium), Pr (praseodymium), Ce (cerium), La (lanthanum), Y (yttrium), or Sc (scandium). In some examples, the at least one rare earth oxide includes an oxide of at least one of Yb, Y, Gd, or Er.

In some examples, CMAS-resistant EBC 18 may include at least one rare earth oxide and silica. In some examples, CMAS-resistant EBC 18 may include at least one rare earth oxide and alumina. The at least one rare earth oxide may include an oxide of at least one of Lu, Yb, Tm, Er, Ho, Dy, Tb, Gd, Eu, Sm, Pm, Nd, Pr, Ce, La, Y, or Sc. In some examples, the at least one rare earth oxide includes an oxide of at least one of Yb, Y, Gd, or Er.

In some examples, CMAS-resistant EBC 18 may include at least one rare earth oxide, silica, and alumina. In some examples, CMAS-resistant EBC 18 may include at least one rare earth oxide, silica, and at least one alkali metal oxide. In some examples, CMAS-resistant EBC 18 may include at least one rare earth oxide, alumina, and at least one alkali metal oxide. In some examples, CMAS-resistant EBC 18 may include at least one rare earth oxide, alumina, silica, and at least one alkali metal oxide. The at least one rare earth oxide may include an oxide of at least one of Lu, Yb, Tm, Er, Ho, Dy, Tb, Gd, Eu, Sm, Pm, Nd, Pr, Ce, La, Y, or Sc. In some examples, the at least one rare earth oxide includes an oxide of at least one of Yb, Y, Gd, or Er.

Regardless of whether CMAS-resistant EBC 18 includes at least one rare earth oxide and alumina; at least one rare earth oxide and silica; at least one rare earth oxide, silica, and alumina; at least one rare earth oxide, alumina, and at least one alkali metal oxide; at least one rare earth oxide, silica, and at least one alkali metal oxide; or at least one rare earth oxide, silica, alumina, and at least one alkali metal oxide, in some examples, CMAS-resistant EBC 18 may include at least one additive. The additive may include, for example, at least one of TiO₂, Ta₂O₅, HfSiO₄, an alkali metal oxide, or an alkali earth metal oxide. CMAS-resistant EBC 18 may include any one or more of these additives alone or in any combination. The additive components may be added to the CMAS-resistant composition to modify one or more desired properties of CMAS-resistant TBC layer 18. For example, the additive components may increase or decrease the reaction rate of CMAS-resistant EBC layer 18 with CMAS, may modify the viscosity of the reaction product from the reaction of CMAS and CMAS-resistant EBC layer 18, may increase adhesion of CMAS-resistant EBC layer 18 to an adjacent layer, such as bond layer 16, may increase or decrease the chemical stability of CMAS-resistant EBC layer 18, or the like.

Additionally or alternatively, in some examples in which CMAS-resistant EBC layer 18 is deposited directly on substrate 12 without a bond layer 16, an additive of up to about 50 wt. % may be added to CMAS-resistant EBC layer 18 to enhance the adhesion between substrate 12 and CMAS-resistant EBC layer 18. The adhesion-enhancing additive may include at least one of silicon or B₂O₃. CMAS-resistant EBC layer 18 may include any one or more of the adhesion-enhancing additives, alone or in any combination. CMAS-resistant EBC layer 18 may include no additives, at least one of TiO₂, Ta₂O₅, HfSiO₄, an alkali metal oxide, or an alkali earth metal oxide alone or in any combination, and/or at least one of the adhesion-enhancing additives, alone or in any combination.

In some examples, CMAS-resistant EBC layer 18 may include between about 1 molar percent (mol. %) and about 99 mol. % of at least one rare earth oxide and up to about 99 mol. % of alumina, with the total of 100 mol. %. In other examples, CMAS-resistant EBC layer 18 may include between about 1 mol. % and about 99 mol. % of at least one rare earth oxide and up to about 99 mol. % of silica, with the total of 100 mol. %. In other examples, CMAS-resistant EBC layer 18 may include between about 1 mol. % and about 99 mol. % of at least one rare earth oxide and up to about 99 mol. % of silica and alumina.

In other examples, a CMAS-resistant EBC layer 18 can include between about 10 mol. % and about 90 mol. % of at least one rare earth oxide and between about 10 mol. % and about 90 mol. % of alumina, with the total of 100 mol. %. In other examples, a CMAS-resistant EBC layer 18 can include between about 10 mol. % and about 90 mol. % of at least one rare earth oxide and between about 10 mol. % and about 90 mol. % of silica, with the total of 100 mol. %. In other examples, CMAS-resistant EBC layer 18 may include between about 10 mol. % and about 90 mol. % of at least one rare earth oxide and between about 10 mol. % and about 90 mol. % of silica and alumina.

In other examples, a CMAS-resistant EBC layer 18 can include between about 20 mol. % and about 80 mol. % of at least one rare earth oxide and between about 20 mol. % and about 80 mol. % of alumina, with the total of 100 mol. %. In other examples, a CMAS-resistant EBC layer 18 can include between about 20 mol. % and about 80 mol. % of at least one rare earth oxide and between about 20 mol. % and about 80 mol. % of silica, with the total of 100 mol. %. In other examples, CMAS-resistant EBC layer 18 may include between about 20 mol. % and about 80 mol. % of at least one rare earth oxide and between about 20 mol. % and about 80 mol. % of silica and alumina.

In other examples, a CMAS-resistant EBC layer 18 may include at least one rare earth oxide and between about 0.1 weight percent (wt. %) and about 5 wt. % alumina and a balance of at least one rare earth oxide, with a total of 100 wt. %. In other examples, a CMAS-resistant EBC layer 18 can may include between less than about 25 wt. % silica and a balance of at least one rare earth oxide, with a total of 100 wt. %. In other examples, a CMAS-resistant EBC layer 18 may include between about 0.1 wt. % and about 5 wt. % alumina, less than about 25 wt. % silica, and a balance of at least one rare earth oxide, with a total of 100 wt. %.

In other examples, a CMAS-resistant EBC layer 18 may include between about 0.1 wt. % and about 3 wt. % alumina and a balance of at least one rare earth oxide, with a total of 100 wt. %. In other examples, a CMAS-resistant EBC layer 18 may include between about 5 wt. % and about 20 wt. % silica and a balance of at least one rare earth oxide, with the total of 100 wt. %. In other examples, a CMAS-resistant layer 18 may include between about 0.1 wt. % and about 3 wt. % alumina, between about 5 wt. % and 20 wt. % silica, and a balance of at least one rare earth oxide, with the total of 100 wt. %.

In other examples, a CMAS-resistant EBC layer 18 may include between about 0.1 wt. % and about 1 wt. % alumina and a balance of at least one rare earth oxide, with a total of 100 wt. %. In other examples, a CMAS-resistant EBC layer 18 may include between about 10 wt. % and about 20 wt. % silica and a balance of at least one rare earth oxide, with the total of 100 wt. %. In other examples, a CMAS-resistant layer 18 may include between about 0.1 wt. % and about 1 wt. % alumina, between about 10 wt. % and 20 wt. % silica, and a balance of at least one rare earth oxide, with the total of 100 wt. %.

In some examples, a CMAS-resistant EBC layer 18 may include between about 0.1 mol. % and about 50 mol. % of at least one additive component selected from TiO₂, Ta₂O₅, HfSiO₄, alkali metal oxides, alkali earth metal oxides, and combinations thereof. For example, a CMAS-resistant EBC layer 18 may include between about 1 mol. % and about 30 mol. % of at least one additive component selected from TiO₂, Ta₂O₅, HfSiO₄, alkali metal oxides, alkali earth metal oxides, and combinations thereof. In some examples, a CMAS-resistant EBC layer 18 may include between about 0.1 wt. % and about 3 wt. % of at least one additive component selected from TiO₂, Ta₂O₅, HfSiO₄, alkali metal oxides, alkali earth oxides, and combinations thereof. In some examples, a CMAS-resistant EBC layer 18 may include between about 0.1 wt. % and about 1 wt. % of at least one additive component selected from TiO₂, Ta₂O₅, HfSiO₄, alkali metal oxides, alkali earth oxides, and combinations thereof.

In some examples, CMAS-resistant EBC layer 18 may be substantially free (e.g., free or nearly free) of hafnia and/or zirconia. As described above, zirconia and hafnia may be susceptible to chemical attach by CMAS, so depositing CMAS-resistant EBC layer 18 substantially free of hafnia and/or zirconia may result in CMAS-resistant EBC layer 18 being more resistant to CMAS attach than a CMAS-resistant EBC layer 18 that includes zirconia and/or hafnia.

CMAS-resistant EBC layer 18 may be deposited with a dense microstructure, a columnar microstructure, or a combination of dense and columnar microstructures. A dense microstructure may be more effective in preventing the infiltration of CMAS, while a columnar microstructure may be more strain tolerant during thermal cycling. A combination of dense and columnar microstructures may be more effective in preventing the infiltration of CMAS than a fully columnar microstructure while being more strain tolerant during thermal cycling than a fully dense microstructure. In some examples, a CMAS-resistant EBC layer 18 with a dense microstructure may have a porosity of less than about 10 vol. %, such as, e.g., less than about 5 vol. %, where porosity is measured as a percentage of pore volume divided by total volume of CMAS-resistant EBC layer 18.

In some examples, CMAS-resistant EBC layer 18 may be deposited as a single layer with a substantially homogeneous composition throughout layer 18. In other examples, CMAS-resistant EBC layer 18 may be deposited including a multiple sub-layers. In some examples, at least one sub-layer may include a different composition than at least one other sub-layer. For example, a sub-layer adjacent to a bond layer 16 may include a mixture of the bond layer components and the CMAS-resistant EBC layer 18, thus reducing stresses induced during thermal cycling from mismatch of properties such as coefficients of thermal expansion between two adjacent layers with different compositions. In some examples, the multiple sub-layers may be compositionally graded, e.g., from a composition more similar to the composition of an adjacent layer to a composition less similar to the composition of the adjacent layer.

In some examples, coating system 14 may include at least one TBC layer 20 deposited over CMAS-resistant EBC layer 18. TBC layer 20 may include, for example, yttria-stabilized zirconia (YSZ), zirconia stabilized by a single or multiple rare earth oxides, hafnia stabilized by a single or multiple rare earth oxides, zirconia-rare earth oxide compounds, such as RE₂Zr₂O₇ (where RE is a rare earth element), and hafnia-rare earth oxide compounds, such as RE₂Hf₂O₇ (where RE is a rare earth element).

In some examples, the present disclosure describes technique for forming coating system, including CMAS-resistant EBC layer 18 and, optionally, one or both of bond layer 16 and TBC layer 20, on a surface of an internal cavity or non-line-of-sight surface of a hot section gas turbine component. The hot section gas turbine component may include, for example, a gas turbine engine blade, vane, blade track, or combustor liner. FIG. 2 is a conceptual, cross-sectional diagram illustrating an example gas turbine engine blade 30. As shown in FIG. 2, the substrate 32 of gas turbine engine blade 30 defines a plurality of internal cavities 34a-34d (collectively, “internal cavities 34”). Although four internal cavities 34 are depicted in FIG. 2, in other examples, gas turbine engine blade 30 may include more or fewer internal cavities 34. The internal cavities 34 also may have different shapes than those shown in FIG. 2. For example, internal cavities 34 may define tortuous flow paths between spars that support a relatively thin sheet of material defining the outer surface of gas turbine engine blade 30. Other types of gas turbine engine components, such as vanes blade tracks, or combustor liners, may define different shapes, including different numbers and/or different shapes of internal cavities 34 and/or non-line-of-sight surfaces.

In some examples, internal cavities 34 may form part of an internal cooling circuit through which cooling fluid flows to facilitate cooling of substrate 32 and allow use of gas turbine engine blade 30 at higher external ambient temperatures. For example, as shown in FIG. 2, each of internal cavities is fluidically coupled to a respective one of film cooling holes 38a-38d (collectively, “film cooling holes 38”), through which the cooling fluid would flow to exit internal cavities 34. Although a single film cooling hole 38 is shown being fluidically connected to each of internal cavities 34, in some examples, multiple film cooling holes 38 may be fluidically connected to a single one of internal cavities 34, and the same or a different number of film cooling holes 38 may be connected to respective ones of internal cavities 34. The fluid channels from internal cavities 34 to film cooling holes 38 also may define non-line-of-sight surfaces to be coated with coating system 14.

In some examples, substrate 32 may include a ceramic, a CMC, or a metal alloy that includes Si, as described with respect to substrate 12 in FIG. 1. As described above, when substrate 32 includes a ceramic, CMC, or metal alloy including Si, water vapor may attack substrate 32 at the operating temperatures of gas turbine engine blade 30. The water vapor may volatilize silica and/or alumina in the substrate, damaging gas turbine engine blade 30. CMAS-resistant EBC layer 18 may protect substrate 32 against attack by water vapor, CMAS, and other reactive species in the fluid flowing through internal cavities 34.

However, internal cavities 34 may be difficult to coat the surfaces 36 of internal cavities 34 with CMAS-resistant layer 18 using conventional coating techniques. For example, surfaces 36 may not be in line-of-sight with the coating source from which CMAS-resistant layer 18 is deposited. Because of this, some coating processes, such as electron beam physical vapor deposition (EB-PVD), plasma spraying, or the like, may deposit CMAS-resistant layer 18 with a non-uniform thickness on surfaces 36, or may leave portions of surfaces 36 uncoated with CMAS-resistant layer 18. This may leave thinly coated or uncoated portions of substrate 32 more vulnerable to chemical attack by water vapor and other chemical species flowing through internal cavities 34.

In contrast, DVD, utilized in the techniques of this disclosure, is a non-line-of-sight EB-PVD process which can provide a uniform coating thickness on internal surfaces 36 of a component, such as a gas turbine engine blade, vane, blade track, or combustor liner. DVD utilizes a gas stream to direct a vapor plume, which may provide a level of substrate exposure for components with complex geometry, such as internal cavities or non-line-of-sight surfaces, allowing a more uniform coating.

FIG. 3 is a flow diagram illustrating an example technique for depositing a CMAS-resistant EBC layer on an internal surface of an article using DVD. FIG. 4 is a schematic diagram of a system including a vapor deposition chamber 52 that may be used to deposit a CMAS-resistant EBC layer 18 on an internal surface of an article 62 using DVD. The technique of FIG. 3 will be described with respect to the system of FIG. 4, although other systems including different or additional components may be used to perform the technique of FIG. 3.

The technique of FIG. 3 includes directing an electron beam 56 at a coating source 58 to create a vapor plume 60 with a predetermined composition (42). As illustrated in FIG. 4, vapor deposition chamber 52 encloses an article 62 including a substrate 70 and defining an internal cavity 64. Vapor deposition chamber 52 also encloses an energy source 54. Energy source 54 is positioned to direct electron beam 56 toward coating source 58. Energy source 54 can output the electron beam 56 at a predetermined energy level to deliver a predetermined energy rate to coating source 58 to vaporize components of coating source 58. In some examples, deposition chamber 24 operates at vacuum conditions that are generated through vacuum port 66.

The composition of vapor plume 60 may depend at least partly on the composition of coating source 58 and relative vapor pressures of the components of coating source 58. Hence, the composition of coating source 58 may be determined based on a desired composition of CMAS-resistant EBC layer 18 and relative vapor pressures of the components in the desired composition of CMAS-resistant EBC layer 18.

For example, rare earth oxides and alumina may have similar vapor pressures at a given pressure and temperature, such that when electron beam 56 is directed at a coating source 58 including at least one rare earth oxide and alumina at a given composition, the resulting vapor plume 60 may have a substantially similar composition. Silica, however, may have a vapor pressure that is greater than a vapor pressure of a rare earth oxide by an order of magnitude or more at a given pressure and temperature. If silica and the at least one rare earth oxide are present in the same coating source 58 and exposed to the same temperature and pressure, the resulting vapor plume 60 may be enriched in silica compared to the composition of the coating source 58.

In some examples, this may be taken into account when determining the composition of coating source 58, such that vapor plume 60 has a predetermined composition that is substantially the same as the desired composition for CMAS-resistant EBC layer 18. For example, when CMAS-resistant EBC layer 18 includes a rare earth oxide and silica, coating source 58 may include a greater concentration rare earth oxide than the desired composition of CMAS-resistant EBC layer 18.

In other examples, multiple coating sources 58 may be used to form the vapor plume 60 with the predetermined composition. In some examples, each of the multiple coating sources includes one or more of the constituents for CMAS-resistant layer 18. In some examples, each respective coating source may include constituents with relatively similar vapor pressures. By controlling the power and/or residence time of the electron beam 56 with respect to the respective coating sources, the vapor flux from each respective coating source can be independently controlled. In some examples, a single electron beam 56 may be utilized, and energy source 54 may steer the electron beam 56 between the multiple coating sources. In other examples, multiple energy sources 54 each generating a respective electron beam 56 may be utilized, and each electron beam 56 may be controlled to provide predetermined energy fluxes to the respective coating sources 58. For example, one electron beam 56 may be used per coating. In this way, the technique of FIG. 3 may produce a vapor plume 60 with a composition selected to result in the predetermined for CMAS-resistant EBC 18.

In some examples, two coating sources may be used to form a CMAS-resistant EBC layer 18 including at least one rare earth oxide, alumina, and silica, with rare earth oxide and alumina combined in a first coating source and silica in a second coating source. In some examples, the rare earth oxide:alumina ratio in the first ingot and the electron beam residence time for each of the two ingots can be determined to produce a vapor plume with the predetermined composition of CMAS-resistant EBC layer 18. Use of multiple ingots in conjunction with a controlled electron beam technology facilitates the fabrication of multi-component CMAS-resistant EBCs in which substantial disparity in vapor pressures exists between coating constituents.

Additional or different coating sources optionally may be used in vapor deposition chamber 52. In some examples, one or more additional coating sources may be used to change the properties of CMAS-resistant EBC layer 18 formed from coating source 58. Additional coating sources may include TiO₂, Ta₂O₅, HfSiO₄, an alkali metal oxide, an alkali earth metal oxide, or combinations thereof.

The technique of FIG. 3 also includes transporting vapor plume 60 to within internal cavity 64 (44) using a gas stream. In some examples, the gas stream may be a transonic gas stream. In some examples, gas stream source 68 may be positioned adjacent to coating source 58. The gas stream may surround vapor cloud 60 coming from coating source 58. In some examples, respective gas stream sources 68 may be positioned adjacent to respective coating sources 58 (when multiple coating sources 58 are used) and be directed past the respective coating sources 58 toward the article 62. Various configurations of gas stream source 68 may include, for example, one gas stream source 68 for each coating source 58 or gas stream sources 68 for some coating sources 58 and no gas stream source 58 for other coating sources 68. Variable gas stream parameters and multiple gas stream sources 68 can create a gas stream path selected for the geometry of article 62. In some examples, vapor plume 60 directed by a gas stream to be deposited on an internal surface of an article 62 may result in enhanced non-line-of-sight coating capability as well as improved coating thickness uniformity.

The technique of FIG. 3 also includes depositing components of CMAS-resistant EBC layer 18 from vapor plume 60 over the surface of internal cavity 64 to form CMAS-resistant EBC layer 18 (46). In some examples, the deposited coating thickness can be between about 0.5 mils (about 12.7 micrometers) and about 10 mils (about 254 micrometers). In some examples, the thickness of the coating can be between about 1 mil (about 25.4 micrometers) and about 3 mils (about 76.2 micrometers).

Although the preceding examples have been primarily described with respect to depositing a CMAS-resistant EBC layer on an internal surface of an article, such as a gas turbine engine component including a ceramic or CMC substrate, in other examples, DVD may be used to deposit coatings having other compositions, both on internal surfaces of articles and external surfaces of articles. Additionally or alternatively, DVD may be used to deposit coatings on articles other than gas turbine engine component including a ceramic or CMC substrate.

For example, the techniques described herein may be used to deposit bond layer 16, TBC layer 20, or both, as part of coating system 14. For deposition of each layer, a respective coating source 58 may include appropriate concentrations of the elements or compounds that form the respective layer, and the coating source 58 may be changed between layers of coating system 14.

As another example, the techniques described herein may be used to deposit an EBC layer with a different composition, which may not be CMAS-resistant. For example, an EBC layer may include mullite, barium strontium aluminosilicate (BSAS), barium aluminosilicate (BAS), strontium aluminosilicate (SAS), at least one rare earth monosilicate (RESiO₅, where RE is a rare earth element), at least one rare earth disilicate (RE₂Si₂O₇, where RE is a rare earth element), or combinations thereof.

The EBC layer may deposited directly on a substrate or on a bond layer. When deposited on a bond layer, the bond layer may include the same or similar composition as described above with respect to bond layer 16. When deposited directly on a substrate, the EBC layer may optionally include up to about 50 wt. % of an adhesion-enhancing additive, such as silicon, B₂O₃, and combinations thereof.

In some examples, the EBC layer may include at least one additive element or compound, such as TiO₂, Ta₂O₅, HfSiO₄, an alkali metal oxide, or an alkali earth metal oxide. The EBC layer may include any one or more of these additives alone or in any combination. The additive components may be added to the EBC composition to modify one or more desired properties of the EBC layer.

In some examples, a TBC layer (e.g., TBC layer 20) may be deposited over the EBC layer. In some examples, the EBC layer may form part of coating system 14, such as a being a layer between substrate 12 and CMAS-resistant layer 18 (with or without bond layer 16), or a layer between CMAS-resistant layer 18 and TBC layer 20.

In some examples, the techniques described herein may be used to deposit a multilayer EBC including multiple layers of rare earth silicates. A rare earth silicate may include a rare earth monosilicate (RESiO₅, where RE is a rare earth element) a rare earth disilicate (RE₂Si₂O₇, where RE is a rare earth element), or both. Suitable rare earth elements include Lu, Yb, Tm, Er, Ho, Dy, Tb, Gd, Eu, Sm, Pm, Nd, Pr, Ce, La, Y, and Sc. In some examples, the rare earth oxide includes an oxide of at least one of Yb, Y, Gd, or Er.

In some examples, rare earth monosilicates and rare earth disilicates may possess different properties. For example, rare earth monosilicates may possess greater chemical stability in the presence of water vapor, which may result in better resistance to recession caused by water vapor attack compared to a rare earth disilicate. As another example, rare earth disilicates may possess a better match of thermal expansion coefficients with a SiC/SiC CMC. This may result in better crack and spallation resistance under thermal cycling compared to a rare earth monosilicate.

In some examples, a multilayer EBC may include an inner layer (closer to the substrate) that includes a rare earth disilicate and an outer layer (farther from the substrate) that includes a rare earth monosilicate. In this way, the multilayer EBC may utilize advantageous properties of both rare earth disilicates and rare earth monosilicates. For example, the inner layer may possess a better match of thermal expansion coefficients with a SiC/SiC CMC, which may result in better crack and spallation resistance under thermal cycling. The outer layer may provide resistance to recession caused by water vapor attack. In some examples, the rare earth disilicate layer may be formed as a substantially nonporous (dense) layer to prevent water vapor penetration, while the outer layer may be formed with a columnar microstructure to facilitate strain tolerance during thermal cycling.

In some examples, a multilayer EBC may include more than two layers. For example, the multilayer EBC may include an inner layer including a rare earth disilitate, an outer layer including a rare earth monosilicate, and a plurality of intervening layers having respective compositions that change from predominantly rare earth disilicate adjacent to the inner layer to predominantly rare earth monosilicate adjacent to the outer layer. The compositional grading between adjacent layers may be gradual or discrete.

In other examples, a multilayer EBC may include alternating rare earth monosilicate and rare earth disilicate layers. For example, a first layer pair may include a rare earth disilicate layer adjacent to the substrate or a bond layer and a rare earth monosilicate layer deposited on the rare earth monosilicate. Subsequent layer pairs may include the same layer configuration. The interfaces between the rare earth disilicate layers and the rare earth monosilicate layers may scatter phonons, which may reduce thermal conductivity of the multilayer EBC compared to an EBC with the same composition and fewer layer interfaces.

The multilayer EBC may be deposited directly on a substrate or on a bond layer. When deposited on a bond layer, the bond layer may include the same or similar composition as described above with respect to bond layer 16. When deposited directly on a substrate, a layer of the multilayer EBC adjacent to the substrate may optionally include up to about 50 wt. % of an adhesion-enhancing additive, such as silicon, B₂O₃, and combinations thereof.

In some examples, at least one layer of the multilayer EBC may include at least one additive element or compound, such as TiO₂, Ta₂O₅, HfSiO₄, an alkali metal oxide, or an alkali earth metal oxide. The at least one layer may include any one or more of these additives alone or in any combination. The additive components may be added to the EBC composition to modify one or more desired properties of the EBC layer.

In some examples, a TBC layer (e.g., TBC layer 20) may be deposited over the multilayer EBC. In some examples, the multilayer EBC may form part of coating system 14, such as a being a set of layers between substrate 12 and CMAS-resistant layer 18 (with or without bond layer 16), or a set of layers between CMAS-resistant layer 18 and TBC layer 20.

In some examples, the technique described herein may be used to deposit a coating including a low thermal conductivity TBC composition. A low thermal conductivity TBC composition may include a base oxide, a primary dopant, a first co-dopant, and a second co-dopant. The base oxide may include or consist essentially of zirconia and/or hafnia. In the current disclosure, to “consist essentially of” means to consist of the listed element(s) or compound(s), while allowing the inclusion of impurities present in small amounts such that the impurities do not substantially affect the properties of the listed element or compound. For example, the purification of many rare earth elements is difficult, and thus the nominal rare earth element may include small amounts of other rare earth elements. This mixture is intended to be covered by the language “consist essentially of”

The primary dopant may include or consist essentially of ytterbia. The first co-dopant may include or consist essentially of samaria, and second co-dopant may include or consist essentially of at least one of lutetia, scandia, ceria, gadolinia, neodymia, or europia. In some embodiments, the low thermal conductivity TBC composition may include zirconia and/or hafnia in combination with additive elements or compounds such that at least some of the stabilized zirconia or hafnia forms a metastable tetragonal-prime crystalline phase, a cubic crystalline phase, or a compound phase (RE₂Zr₂O₇ or RE₂Hf₂O₇, where RE is a rare earth element). The low thermal conductivity TBC composition may be essentially free of yttria.

In some examples, the low thermal conductivity TBC composition may consist essentially of a base oxide, a primary dopant, a first co-dopant, and a second co-dopant. The base oxide may be selected from zirconia, hafnia, and combinations thereof. The primary dopant may consist essentially of ytterbia. The first co-dopant may consist essentially of samaria. The second co-dopant may be selected from the group consisting of lutetia, scandia, ceria, gadolinia, neodymia, europia, or combinations thereof. The low thermal conductivity TBC composition may be essentially free of yttria.

In some examples, the primary dopant is present in the low thermal conductivity TBC composition in an amount greater than either the first co-dopant or the second co-dopant. In various examples, the primary dopant may be present in an amount less than, equal to, or greater than the total amount of the first co-dopant and the second co-dopant.

In some examples, the low thermal conductivity TBC composition includes between about 2 mol. % and about 40 mol. % of the primary dopant. In other examples, the low thermal conductivity TBC composition includes between about 20 mol. % and about 40 mol. % of the primary dopant, between about 2 mol. % and about 20 mol. % of the primary dopant, between about 2 mol. % and about 10 mol. % of the primary dopant, between about 2 mol. % and about 5 mol. % of the primary dopant.

In some examples, the low thermal conductivity TBC composition includes between about 0.1 mol. % and about 20 mol. % of the first co-dopant. In other examples, the low thermal conductivity TBC composition includes between about 10 mol. % and about 20 mol. % of the first co-dopant, between about 2 mol. % and about 10 mol. % of the first co-dopant or between about 0.5 mol. % and about 3 mol. % of the first co-dopant.

In some examples, the low thermal conductivity TBC composition includes between about 0.1 mol. % and about 20 mol. % of the second co-dopant. In other examples, the low thermal conductivity TBC composition includes between about 10 mol. % and about 20 mol. % of the second co-dopant, between about 2 mol. % and about 10 mol. % of the second co-dopant, or between about 0.5 mol. % and about 3 mol. % of the second co-dopant.

The composition of the low thermal conductivity TBC composition provides a desired phase constitution. For a low thermal conductivity TBC composition that includes zirconia and/or hafnia, a primary dopant, a first co-dopant, and a second co-dopant, accessible phase constitutions include metastable tetragonal-prime, cubic, and compound (RE₂Zr₂O₇ and RE₂Hf₂O₇, where RE is a rare earth element). To achieve a RE₂O₃—ZrO₂ (and/or HfO₂) compound phase constitution, the low thermal conductivity TBC composition includes between about 20 mol. % and about 40 mol. % primary dopant, between about 10 mol. % and about 20 mol. % first co-dopant, between about 10 mol. % and about 20 mol. % second co-dopant, and the balance base oxide (hafnia and/or zirconia) and any impurities present. To achieve a cubic phase constitution, the low thermal conductivity TBC composition includes between about 4 mol. % and about 10 mol. % primary dopant, between about 1 mol. % and about 5 mol. % first co-dopant, between about 1 mol. % and about 5 mol. % second co-dopant, and a balance base oxide (zirconia and/or hathia) and any impurities present. In some examples, to achieve a metastable tetragonal phase constitution, the low thermal conductivity TBC composition includes between about 2 mol. % and about 5 mol. % primary dopant, between about 0.5 mol. % and about 3 mol. % first co-dopant, between about 0.5 mol. % and about 3 mol. % second co-dopant, and a balance base oxide and any impurities present.

In some examples the low thermal conductivity TBC composition may be deposited from a single coating source including all of the constituents of the low thermal conductivity TBC composition. In other examples, the low thermal conductivity TBC composition may be deposited from multiple coating sources. For example, a first coating source may include the base oxide and a second coating source may include the primary dopant, the first co-dopant, and the second co-dopant.

In some examples, by utilizing multiple coating sources, multiple layers including different proportions of base oxide, primary dopant, first co-dopant, and second co-dopant may be formed in a single process without switching coating sources. For example, by changing the relative residence time or relative energy delivery rate of the electron beam to each coating source, the composition of the vapor plume and coating may be changed. In some examples, a multilayer coating including a first, inner low thermal conductivity layer having a tetragonal prime phase constitution, a second, middle low thermal conductivity layer having a cubic phase constitution, and a third, outer layer having a tetragonal prime phase constitution by varying the relative residence time or relative energy delivery rate of the electron beam to each coating source. The first, inner layer may possess relatively low thermal conductivity (about 1.4 watts per meter Kelvin; w/m-K) and acceptable thermal cycling resistance, the second, middle layer may possess lower thermal conductivity (about 1.0 w/m-K), and the third, outer layer may possess relatively low thermal conductivity (about 1.4 w/m-K) and acceptable erosion resistance.

In some examples, the low thermal conductivity TBC composition may form part of coating system 14, such as a being between substrate 12 and CMAS-resistant layer 18 (with or without bond layer 16), or between CMAS-resistant layer 18 and TBC layer 20, or may be used as TBC layer 20.

### EXAMPLES

### Example 1

FIGS. 5A and 5B, respectively, show DVD-processed CMAS-resistant EBC coated substrates from one embodiment of the present application after 100 h steam cycling without CMAS attack (5A) and with CMAS attack (5B). The CMAS-resistant EBC in FIGS. 5A and 5B included about 70 wt. % Yb₂O₃, about 25 wt. % SiO₂, and about 5 wt. % Al₂O₃. The CMAS-resistant EBC was deposited using DVD from two ingots. The first ingot included ytterbia and alumina. The second ingot included silica. The evaporation mass ratio for the technique was Yb₂O₃+10 wt. % Al₂O₃:SiO₂=1.14. For the electron beam, the total e-beam power was equal to 22.3 kW. The e-beam scanning frequency was between approximately 5 kHz and approximately 10 kHz. The e-beam relative residence time (between the two ingots) was: first coating source=57.73% and second coating source=42.27%.

The EBC in FIGS. 5C and 5D included Yb₂Si₂O₇. The EBC was deposited using DVD from two ingots. The first ingot included ytterbia. The second ingot included silica. The evaporation mass ratio for the technique was Yb₂O₃:SiO₂=1.14. For the electron beam, the total e-beam power was equal to 22.3 kW. The e-beam scanning frequency was between approximately 5 kHz and approximately 10 kHz. The e-beam relative residence time (between the two ingots) was: first coating source=57.73% and second coating source=42.27%.

Note that the CMAS reaction zone is limited to the surface of the coating (5B). In comparison, FIG. 5C of an EBC coated substrate had been penetrated by CMAS and the EBC was delaminated with the same CMAS exposure. The delaminated EBC system can be compared to a coating that did not undergo CMAS attack in FIG. 5D.

### Example 2

An example CMAS-resistant EBC was deposited on SiC/SiC CMC coupon using DVD. The CMAS-resistant EBC included about 70 wt. % Y₂O₃, about 25 wt. % SiO₂, and about 5 wt. % Al₂O₃. Prior to depositing the CMAS-resistant EBC, the vapor pressure values and source compositions were determined for a coating including yttrium oxide, alumina, and silica. A first coating source included a composition of 90 wt. % Y₂O₃+10 wt. % Al₂O₃. The second coating source included SiO₂.

About 148.18 g of the first coating source was evaporated to form a first vapor including yttrium oxide and alumina. About 129.6 g of the second coating source was evaporated to form a second vapor including silica. The evaporation mass ratio for the technique was Y₂O₃+10 wt % Al₂O₃:SiO₂=1.14. The DVD process was conducted with a deposition time of 35 minutes. For the electron beam, the total e-beam power was equal to 22.3 kW. The e-beam scanning frequency was between approximately 5 kHz and approximately 10 kHz. The e-beam relative residence time (between the two ingots) was: first coating source=57.73% and second coating source=42.27%.

### Example 3

FIGS. 6A and 6B are micrographs illustrating a cross-section of an example SiC/SiC CMC gas turbine vane inner trailing edge coated with an EBC. The EBC includes ytterbium disilicate. The EBC was deposited using DVD from two ingots. The first ingot included ytterbia. The second ingot included silica. The evaporation mass ratio for the technique was Yb₂O₃:SiO₂=1.14. For the electron beam, the total e-beam power was equal to 22.3 kW. The e-beam scanning frequency was between approximately 5 kHz and approximately 10 kHz. The e-beam relative residence time (between the two ingots) was: first coating source=57.73% and second coating source=42.27%. As shown in FIGS. 6A and 6B, DVD facilitate coating of the inner surfaces of CMC gas turbine vane inner trailing edge with an EBC with a relatively uniform thickness. An EBC including ytterbium disilicate may protect the substrate from water vapor-enhanced oxidation and may provide thermal insulation to the substrate.

### Example 4

FIG. 7 is micrographs illustrating a cross-section of an example SiC/SiC CMC substrate coated with a multilayer EBC. The CMC substrate was first coated with a Si bond layer. A first EBC layer including ytterbium disilicate was deposited on the Si bond layer using DVD. The first EBC layer had a dense microstructure. The first EBC layer was deposited using DVD from two ingots. The first ingot included ytterbia. The second ingot included silica. The evaporation mass ratio for the technique was Yb₂O₃:SiO₂=1.14. For the electron beam, the total e-beam power was equal to 22.3 kW. The e-beam scanning frequency was between approximately 5 kHz and approximately 10 kHz. The e-beam relative residence time (between the two ingots) was: first coating source=57.73% and second coating source=42.27%. A second EBC layer including ytterbium monosilicate was deposited on the first EBC layer using DVD. The second EBC layer had a columnar microstructure.

The second EBC layer was deposited using DVD from two ingots. The first ingot included ytterbia. The second ingot included silica. For the electron beam, the total e-beam power was equal to 22.3 kW. The e-beam scanning frequency was between approximately 5 kHz and approximately 10 kHz. The e-beam relative residence time (between the two ingots) was: first coating source=79% and second coating source=21%. The coated article was exposed to steam cycling for 100 hours. Each cycle included heating the coated article to about 1316° C. for about 1 hour.

### Example 5

FIGS. 8A and 8B are micrographs illustrating a superalloy substrate coated with a low thermal conductivity TBC having a tetragonal prime phase constitution. The low thermal conductivity TBC having a tetragonal prime phase constitution was deposited using DVD from one ingot. For the electron beam, the total e-beam power was equal to 32 kW. The e-beam scanning frequency was between approximately 5 kHz and approximately 10 kHz. The superalloy substrate was a nickel-based superalloy available under the trade designation CMSX-4 from Cannon Muskegon Corp., Muskegon, Mich. FIGS. 8A and 8B illustrate that the low thermal conductivity TBC having a tetragonal prime phase constitution had a columnar microstructure.

Various examples have been described. These and other examples are within the scope of the following claims.

What is claimed is:

1. A method comprising:
directing an electron beam at a coating source to create a vapor plume, wherein the coating source comprises alumina and at least one rare earth oxide;
transporting the vapor plume using a gas stream provided adjacent to the coating source to within an internal cavity defined by a surface of a substrate of a gas turbine engine blade, vane, blade track, or combustor liner, and wherein the substrate comprises at least one of a silicon-containing ceramic or a ceramic matrix composite; and
depositing the alumina and the at least one rare earth oxide from the vapor plume over the surface of the internal cavity to form a calcia-magnesia-alumina-silicate (CMAS)-resistant environmental barrier coating (EBC) comprising the alumina and the at least one rare earth oxide.

2. The method of claim 1, wherein the coating source further comprises silica and wherein depositing the alumina and the at least one rare earth oxide from the vapor plume over the surface of the internal cavity comprises depositing the alumina, the silica, and the at least one rare earth oxide from the vapor plume over the surface of the internal cavity to form a CMAS-resistant EBC comprising the alumina, the silica, and the at least one rare earth oxide.

3. The method of claim 2, wherein the coating source comprises sufficient alumina, silica, and the at least one rare earth oxide to deposit a CMAS-resistant EBC comprising between about 0.1 wt. % and about 5 wt. % alumina, less than about 25 wt. % silica, and a balance of the at least one rare earth oxide.

4. The method of claim 1, wherein the coating source further comprises at least one of TiO₂, Ta₂O₅, HfSiO₄, an alkali metal oxide, or an alkali earth metal oxide, and wherein depositing the alumina and the at least one rare earth oxide from the vapor plume over the surface of the internal cavity comprises depositing the alumina, the at least one rare earth oxide, and the at least one of TiO₂, Ta₂O₅, HfSiO₄, an alkali metal oxide, or an alkali earth metal oxide from the vapor plume over the surface of the internal cavity to form a CMAS-resistant EBC comprising the alumina, the at least one rare earth oxide, and the at least one of TiO₂, Ta₂O₅, HfSiO₄, an alkali metal oxide, or the alkali earth metal oxide.

5. The method of claim 4, wherein the coating source comprises a sufficient amount of the at least one of TiO₂, Ta₂O₅, HfSiO₄, the alkali metal oxide, or the alkali earth metal oxide to form a CMAS-resistant EBC comprising between about 0.1 wt. % and about 3 wt. % of the at least one of TiO₂, Ta₂O₅, HfSiO₄, the alkali metal oxide, or the alkali earth metal oxide.

6. The method of claim 1, wherein depositing the alumina and the at least one rare earth oxide from the vapor plume over the surface of the internal cavity comprises depositing the alumina and the at least one rare earth oxide from the vapor plume on a bond layer formed on the surface of the internal cavity.

7. The method of claim 1, further comprising depositing a thermal barrier coating layer over the CMAS-resistant EBC.

8. A method comprising:
directing an electron beam at a first coating source to create a first vapor plume, wherein the first coating source comprises alumina and at least one rare earth oxide;
directing the electron beam at a second coating source to create a second vapor plume, wherein the second coating source comprises silica;
transporting the first vapor plume using a first gas stream provided adjacent to the first coating source to within an internal cavity defined by a surface of a substrate of a gas turbine engine blade, vane, blade track, or combustor liner, and wherein the substrate comprises at least one of a silicon-containing ceramic or a ceramic matrix composite; and
transporting the second vapor plume using a second gas stream provided adjacent to the second coating source to within the internal cavity defined by the surface of the substrate of the gas turbine engine blade, vane, blade track, or combustor liner; and
depositing the alumina and the at least one rare earth oxide from the first vapor plume and the silica from the second vapor plume over the surface of the internal cavity to form a calcia-magnesia-alumina-silicate (CMAS)-resistant environmental barrier coating (EBC) comprising the alumina, the silica, and the at least one rare earth oxide.

9. The method of claim 8, wherein directing the electron beam at the first coating source comprises directing the electron beam at the first coating source for a first residence time, and wherein directing the electron beam at the second coating source comprises directing the electron beam at the second coating source for a second, different residence time.

10. The method of claim 9, wherein the first residence time and the second residence time are determined based at least in part on the vapor pressure of the alumina, the vapor pressure of the silica, the vapor pressure of the at least one rare earth oxide, and the composition of the CMAS-resistant barrier layer.

11. The method of claim 8, wherein directing the electron beam at the first coating source comprises directing a first electron beam from a first energy source at the first coating source, and wherein directing the electron beam at the second coating source comprises directing a second, different electron beam from a second, different energy source at the second coating source.

12. The method of claim 8, further comprising:
directing the electron beam at a third coating source to create a third vapor plume, wherein the third coating source comprises at least one of TiO₂, Ta₂O₅, HfSiO₄, an alkali metal oxide, or an alkali earth metal oxide;
transporting the third vapor plume using a third gas stream provided adjacent to the third coating source to within the internal cavity defined by the surface of the substrate of the gas turbine engine blade or vane; and
depositing the at least one of TiO₂, Ta₂O₅, HfSiO₄, the alkali metal oxide, or the alkali earth metal oxide from the third plume with the silica, the alumina, and the at least one rare earth oxide to form the CMAS-resistant EBC.

13. The method of claim 12, wherein the first coating source comprises a sufficient amount of the alumina and the at least one rare earth oxide, the second coating source comprises a sufficient amount of silica, and the third coating source comprises a sufficient amount of the at least one of TiO₂, Ta₂O₅, HfSiO₄, the alkali metal oxide, or the alkali earth metal oxide to form a CMAS-resistant EBC comprising between about 0.1 wt. % and about 5 wt. % alumina; less than about 25 wt. % silica; and between about 0.1 wt. % and about 3 wt. % of the at least one of TiO₂, Ta₂O₅, HfSiO₄, the alkali metal oxide, or the alkali earth metal oxide; and a balance of the at least one rare earth oxide.

14. The method of claim 8, wherein the first coating source comprises a sufficient amount of the alumina and the at least one rare earth oxide, the second coating source comprises a sufficient amount of silica to form a CMAS-resistant EBC comprising between about 0.5 wt. % and about 3 wt. % alumina, between about 5 wt. % and about 20 wt. % silica, and a balance of the at least one rare earth oxide.

15. The method of claim 8, wherein the first coating source comprises a sufficient amount of the alumina and the at least one rare earth oxide, the second coating source comprises a sufficient amount of silica to form a CMAS-resistant EBC comprising between about 0.5 wt. % and about 1 wt. % alumina, between about 10 wt. % and about 20 wt. % silica, and a balance of the at least one rare earth oxide.

16. The method of claim 8, wherein depositing the alumina and the at least one rare earth oxide from the first vapor plume and the silica from the second vapor plume over the surface of the internal cavity comprises depositing the alumina and the at least one rare earth oxide from the first vapor plume and the silica from the second vapor plume over the surface of the internal cavity on a bond layer formed on the surface of the internal cavity.

17. The method of claim 8, further comprising depositing a thermal barrier coating layer over the CMAS-resistant EBC.
